(19) United States
(12) Patent Application Publication
(10) Pub. No.: US 2011/0101531 A1
(43) Pub. Date: May 5, 2011

(54) THERMO-MECHANICAL STRESS IN SEMICONDUCTOR WAFERS

(75) Inventors: Francois Neuilly, Colomby-Sur-Thaon (FR); Paul Messaoudi, Bernieres-Sur-Mer (FR)

(73) Assignee: NXP B.V., Eindhoven (NL)

(21) Appl. No.: 12/995,441

(22) PCT Filed: May 21, 2009
(86) PCT No.: PCT/IB09/52134

§ 371 Date: Dec. 1, 2010

(30) Foreign Application Priority Data
May 30, 2008 (EP) 08290501.9
May 21, 2009 (IB) PCT/IB2009/052134

(51) Int. Cl. H01L 23/532; H01L 23/52; H01L 23/48

(52) U.S. Cl. 257/751; 257/773; 257/774; 257/E23.011; 257/E23.141; 257/E23.154

(57) ABSTRACT

An apparatus for restricting the thermo-mechanical stress in semiconductor wafers both during manufacture, and during the operating lifetime of the semiconductor devices and systems formed on the wafer. An electrically conductive track 8 can be formed with a stopper 16 which can be positioned at least at one end of the electrically conductive track 8. The differential expansion during heating of electrically conductive tracks 8 with respect to a semiconductor wafer 4 can be restricted by the stopper 16.

### BACKGROUND OF THE INVENTION

This invention relates to semiconductor wafers or dies comprising a semiconductor substrate material, typically silicon, and one or more electrically conducting tracks.

Semiconductor wafers or dies are used as the substrate in the manufacture of integrated circuits which comprise electrically conducting tracks typically made from copper or aluminium. These electrically conducting tracks may be provided on several layers above, on or through the surface of the semiconductor substrate.

A System in Package, from here on referred to as a SiP, consists of a number of integrated circuits enclosed in a single package or module. Silicon dies containing integrated circuits may be stacked vertically on a substrate. The integrated circuits can be connected using a number of methods such as by using fine wires that are buried in the package or by solder bumps fabricated on the integrated circuit which are used to join stacked integrated circuits together. Where solder bumps are used then connections can be made using flip chip technology wherein one die is flipped over to connect the solder bumps formed on the same side of the die as the electronic circuits. Alternatively, solder bumps may be formed on the reverse side of the die and connections made to the bumps using through silicon vias which are filled with metal to form the electrical connection to the circuit. This allows multiple dies to be stacked on top of one another, resulting in a very compact form factor which is required for products such as mobile phones.

During the fabrication process of integrated circuits or SiPs and also in the lifetime of operation of the devices, the materials are subject to repeated heating and cooling cycles. Because the different materials used typically expand and contract in varying amounts (owing to their differing thermal coefficients of expansion), this induces thermo-mechanical stresses in the integrated circuit or SiP resulting in a defect which can either result in an immediate failure or reduces the operating lifetime. Where there is a large difference in the thermal coefficient of expansion between the materials, there is a greater risk of a failure. For example copper, which is commonly used for forming the metal tracks in horizontal layers and in vias between layers, has a thermal expansion coefficient which is approximately five times greater than that of silicon. Examples of failure mechanisms which can occur due to the different thermal expansion and contraction of copper versus silicon are:
top and bottom metallisation de-lamination or a lifting up of stacked dies in a SiP;
the metal via is cut causing an open circuit due to plastic deformation because of repeated temperature variations;
Wafer or die breakage due to high mechanical stress in the silicon; and
failure of metallization in a layer due to via bulging.

FIG. 1 illustrates a typical problem caused by thermo-mechanical stresses. A via 2 is formed in the semiconductor material 4 and/or dielectric 10 and filled with a metal such as copper 8. A further metal layer 9 is formed on the surface of the dielectric 10. When the material is heated, the via can bulge because of the increased expansion of the metal compared to the dielectric or semiconductor material which can cause the metal track to delaminate from the surface 6.

Failures may occur in particular in through-silicon-vias here on referred to as TSV since while 100-silicon crystal is very strong against tensile or compressive stresses; it is known to be weaker against shear stresses. IBM research report RC23867, Feb. 3, 2006 discusses a CMOS-compatible process for fabricating electrical through-vias in silicon using either copper or tungsten to form the electrical connection. The wafers fabricated using tungsten vias were shown to have a higher reliability then the copper vias but also have a higher electrical resistance. An analysis technique to show the effects of thermal stress on TSVs is discussed by Miranda and Moll in their paper entitled “Thermo-mechanical characterization of copper through-wafer interconnects” 2006 IEEE Electronic Components and Technology Conference.

US Pat. No. 2003/0006509 describes a method of preventing displacement of a semiconductor element and a wiring pattern of a wiring substrate so as to ensure the connection of the semiconductor element and the wiring pattern. This method is used during the bonding of a semiconductor element to a substrate in the film form by thermo-compression bonding. JP6188331A describes a low-expansion metal foil and laminated board for printed circuit boards. U.S. Pat. No. 5,615,224 describes an apparatus and method for stabilization of the bandgap and associated properties of semiconductor electronic and optoelectronic devices. JP7096634 describes on an LED writer and image forming apparatus to prevent positional deviations of dots of an LED by preventing thermal expansion of a printed circuit board. Tagami et al. discuss using a control layer to improve via stability in their paper entitled “The effect of stress control layer on via-stability in organic low-k/Cu Dual damascene Interconnects under Thermal Cycle Stress” published in the IEEE Interconnect Technology Conference proceedings 2003.

U.S. Pat. No. 6,307,268 B1 describes an interconnect structure for use in semiconductor devices comprising: (a) a thin and elongated aluminium wire connected to a first metal structure and (b) a plurality of regularly spaced dummy tungsten plugs which are connected to the aluminium wire at one end and are buried in an underlying dielectric layer so that it is insulated at the other end. These dummy plugs absorb the mobile aluminium atoms generated through stress-induced migration when the interconnect structure is subject to a rapid temperature change. This relieves pressure on the functional via interconnections which in this case are also typically made of tungsten; these otherwise can protrude into a second metal layer above the first metal layer and damage the second metal structure.

Accordingly the invention aims to address failures caused by thermo-mechanical stresses in integrated circuits and SiP packaging.

### SUMMARY OF THE INVENTION

Various aspects of the invention of the invention are defined in the accompanying claims.

According to a first aspect of the invention, there is provided an apparatus comprising:
a first semiconductor substrate comprising a first material;
at least one electrically conductive track located on or in the substrate, wherein the electrically conductive track comprises a second material having a thermal expansion coefficient that is different to a thermal expansion coefficient of the first material;
and at least one stopper positioned to at least partially restrict thermal expansion of the electrically conductive track relative to the semiconductor substrate.

This invention can address the problem of thermo-mechanical stresses described above by use of a stopper. The stopper can restrict the movement of the electrically conductive tracks relative to the semiconductor substrate, reducing the likelihood of a failure caused by thermo-mechanical stresses. Advantageously the stopper can reduce the expansion of the electrically conductive track in a direction which can cause a failure. As a consequence, the stresses in the semiconductor wafer or die may increase in other directions which are less likely to cause a failure.

In an example embodiment, the stopper can be made from a material that has a lower thermal expansion coefficient and/or a higher Young's modulus than the electrically conductive track.

In another embodiment, the stopper may be anchored in the substrate of the semiconductor wafer or die. This can reduce the thermal expansion of electrically conductive tracks located on the surface of the semiconductor substrate. In this embodiment the electrically conductive track can be formed on the surface of the wafer and the stopper, having a width greater than that of the electrically conductive track, can be used to restrict the thermal expansion.

In a further example embodiment, a via in a semiconductor substrate is partially filled with a material such as copper and a stopper made from a further material such as tungsten. The tungsten stopper can restrict the expansion of the copper via and also forms part of the electrically conducting track. This embodiment can improve the reliability by:
improving the reliability of the via by reducing delamination and metal via cut; and/or
reducing mechanical shear stresses, which can reduce the number of silicon wafers that are broken.

Another example embodiment comprises a grid of electrically conductive tracks in which thermal expansion can be restricted by a stopper located at the point of intersection of the tracks on the grid.

A further embodiment comprises a number of semiconductor dies stacked on top of each other, with TSVs that are used to form the required electrical connections between the dies in the stack.

In another aspect of the invention, there is provided an integrated circuit chip that comprises the apparatus described above.

The above summary of the present invention is not intended to describe each embodiment or every implementation of the present invention. The figures and detailed description that follow more particularly exemplify these embodiments.

### BRIEF DESCRIPTION OF THE DRAWINGS

Embodiments of the present invention will be described hereinafter, by way of example only, with reference to the accompanying drawing in which like reference signs relate to like elements and in which:

FIG. 1 illustrates the problem caused by via bulging due to differential thermal expansion;

FIG. 2 illustrates a structure comprising a via with a stopper in accordance with an embodiment of the invention;

FIG. 3 illustrates an alternative structure comprising a via with a stopper in accordance with an embodiment of the invention;

FIG. 4a shows a cross-section of a structure which comprises a stopper anchored in the substrate material used as a stopper for a track formed on the surface of the wafer or subsequent layer, in accordance with a further embodiment of the invention;

FIG. 4b shows a plan view of stopper configurations which may be used for tracks formed on the surface of a wafer or subsequent layer in accordance with an embodiment of the invention;

FIG. 5 illustrates an example embodiment wherein the stoppers are used in a grid for example in a CMOS sensor array; and

FIG. 6 illustrates the use of TSVs in a stacked die arrangement in accordance with a further embodiment of the invention.

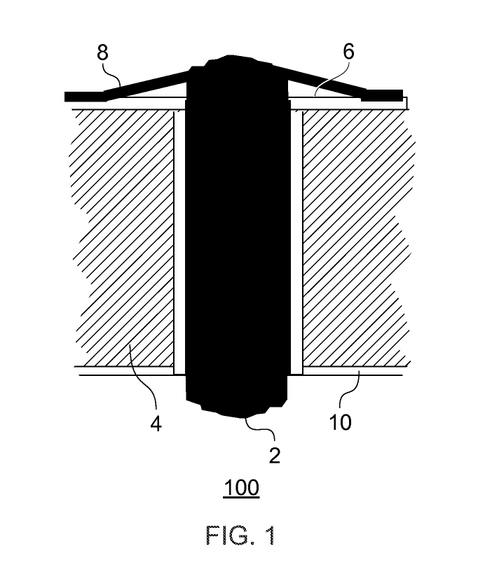

### DESCRIPTION

The invention aims to reduce the thermo-mechanical stresses which may cause an electrical failure in semiconductor devices and/or systems formed by a plurality of semiconductor devices stacked on top of each other to form a SiP. The invention provides an apparatus for mitigating the effects of the thermo-mechanical stress in semiconductor wafers both during manufacture, and during the operating lifetime of the semiconductor devices and systems formed on the wafer. In accordance with the invention, an electrically conductive track can be formed with a stopper which can be positioned at least at one end of the electrically conductive track. The differential expansion during heating of electrically conductive tracks with respect to a semiconductor wafer can be restricted by the stopper. Typically the material used in semiconductor wafer is 100-silicon. Example embodiments of the invention and advantages of the embodiments are described in further detail in the following sections. As described below, the invention can be applied to tracks that run through a semiconductor substrate or to tracks that run along the surface of the substrate or to tracks that run on the surface of materials deposited on the substrate.

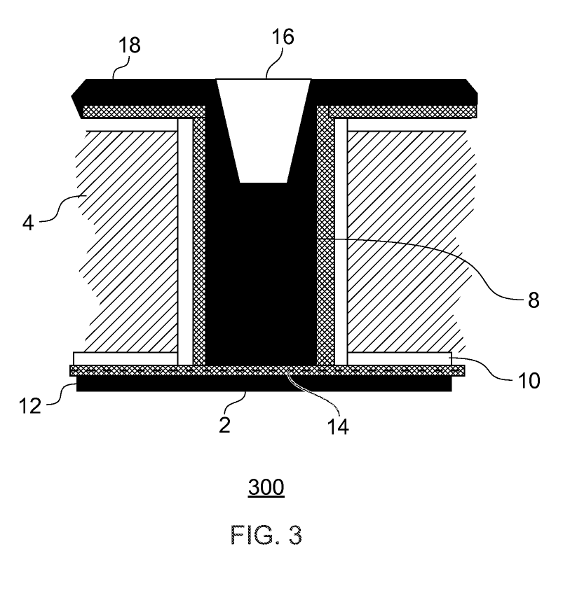

FIG. 3 illustrates an example embodiment of the invention. In the semiconductor device 200, a dielectric layer 10 can be formed on the surface of the substrate 4. This layer can comprise a material such as silicon oxide which can be used to electrically isolate the different metal layers formed on the integrated circuit from each other. A via 2 can be formed on or in a semiconductor substrate 4 in this embodiment. The via 2 is formed by first patterning the wafer typically using a photolithographic method. After patterning the vias are formed by etching through the substrate using chemical etching, deep reactive ion plasma etching or other means through the surface of the layer 10. For a TSV, a via 2 can be formed through the substrate 4 by the method previously described. A seed layer 14 comprising an electrically conductive material such as an alloy of titanium and copper or titanium nitride or ruthinium can be formed one side of the substrate 4 typically using RF magnetron sputtering. This can act as a diffusion barrier which protects the substrate from contamination by the electrically conductive material 8 used to fill the via 2, and can also provide an adhesion layer for the material 8. A metal layer 12 can be formed on one side of the wafer comprising a material such as copper, aluminium or gold. The via 2 can be partially filled with an electrically conducting material 8 such as copper, aluminium or gold adjacent to the layer 14. The filling of the via 2 with an electrically conducting material 8 on top of the seed layer can be done using a method such as electroplating. A stopper 16 can be formed on the surface of the electrically conductive track 8 using a method such as electroplating or physical vapour deposition. A method such as chemical-mechanical planarization is then used to remove the excess stopper 16 material prior to the deposition of subsequent metal and/or dielectric layers. The material comprising the stopper 16 can have a lower coefficient of thermal expansion and/or a higher value of Young's Modulus than the electrically conductive track 8 and so expands less then the electrically conductive track when heated as well as restricting the thermal expansion of the track 8. Preferably the stopper 16 comprises a material that has a lower coefficient of thermal expansion and/or a higher value of Young's modulus than the electrically conductive track 8 which can further restrict the expansion of the track 8. For example, the material comprising the stopper 16 can have a coefficient of thermal expansion which is less than twice the value of the coefficient of thermal expansion of the substrate 4. As a further example, the material comprising the stopper can have a value of Young's modulus which is at least twice the value of the electrically conductive track 8. The material comprising the stopper can have a value of Young's modulus which is of the same order of magnitude as the value of Young's modulus of the substrate 4.

A further metal layer 18 comprising a material such as copper, aluminium or gold can be formed adjacent to the stopper. Hence the material 8 and stopper 16 form an electrical connection between the different metal layers 12, 18 of the semiconductor device 200 which otherwise are physically separated and electrically isolated by the semiconductor substrate 4 and/or dielectric layer 10.

Since the stopper 16 can restrict the differential thermal expansion of the electrically conductive track 8 in the vertical direction, this can improve reliability by preventing de-lamination of the further metal layer 18 which may otherwise cause an electrical failure in a semiconductor device. As a further advantage the stopper 16 can improve reliability by reducing sheer stresses in the semiconductor substrate 4 caused by the differential thermal expansion of the electrically conductive track 8 with respect to the semiconductor substrate 4. Sheer stresses can cause an electrical failure due to the semiconductor substrate cracking. Although tensile stresses in the semiconductor wafer may increase as a consequence, it is known that 100-silicon, which is commonly used to form the semiconductor substrate 4, is much more resilient to tensile stresses than sheer stresses. The embodiment therefore takes advantage of this property of the silicon to improve reliability. It can further improve reliability by preventing failures due to via cut wherein the electrically conductive track 8 in the via 2 suffers from plastic deformation from repeated heated and cooling cycles either in manufacture or during the operating lifetime of the device. The plastic deformation of the via 2 can cause an open circuit between the via 2 and a metal track 12 resulting in a device failure.

The stopper 16 can, for example comprise an electrically conductive material such as tungsten or molybdenum. A stopper of this kind advantageously forms the electrical connection to an electrically conductive track formed on a subsequent layer 13 adjacent to the stopper 16. Furthermore, a combination of a via partially filled with an electrically conductive material 8 such as copper and a stopper 16 comprising an electrically conductive material such as tungsten has a lower resistance than a via comprising tungsten.

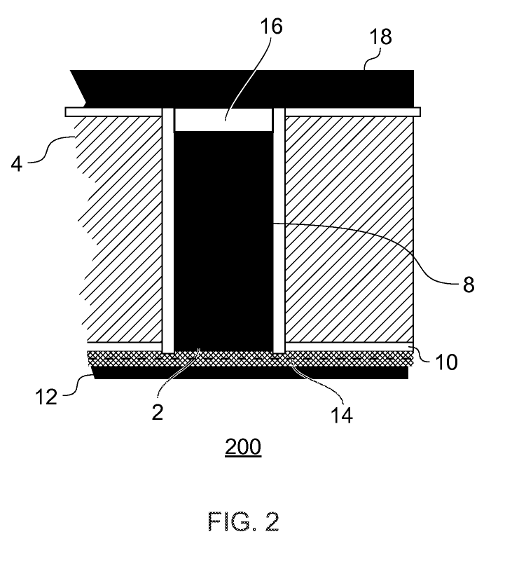

A further example embodiment of the invention is shown in FIG. 3. The formation of a via 2, a dielectric layer 10, and a seed layer 14 are as described in the embodiment illustrated in FIG. 2. The via 2 can be partially filled with an electrically conducting material 8 such as copper, aluminium or gold and simultaneously the further metal layer 18 is formed with the same material 8 used to fill the via 2 by a method such as electroplating. The material 8 forms an electrically conductive track between the different layers of a semiconductor device. A stopper 16 comprising a material such as tungsten or molybdenum can be formed at least partially in the via 2, in the hole formed during the filling of the via 2 and formation of the metal track 18. A method such as chemical-mechanical planarization is then used to remove the excess material forming the stopper 16 and further metal layer 18 prior to the deposition of subsequent metal and/or dielectric layers

Advantageously the stopper 16 restricts the differential thermal expansion of the electrically conductive track 8 in the via 2 with respect to the semiconductor substrate 4 in a substantially vertical direction. As a further advantage the stopper 16 can restrict the differential thermal expansion of the metal track 18 in a substantially horizontal direction. The stopper 16 improves reliability by reducing sheer stresses in the wafer due to differential thermal expansion. Advantageously the stopper 16 improves reliability by restricting via bulging and so preventing the de-lamination of metal track 18.

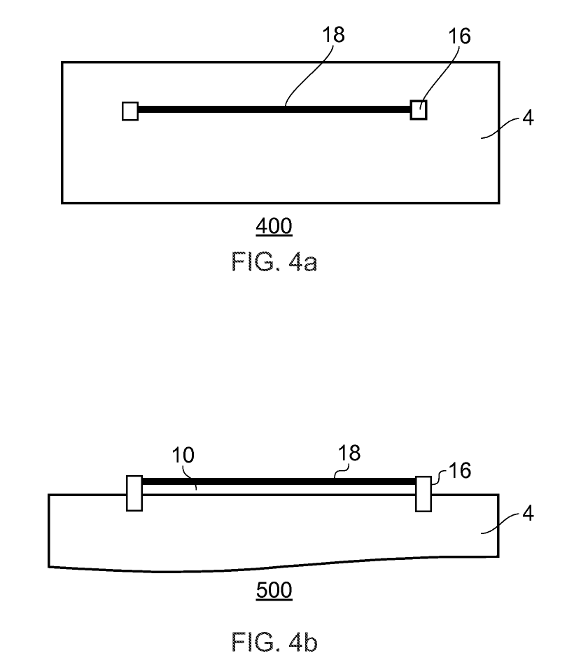

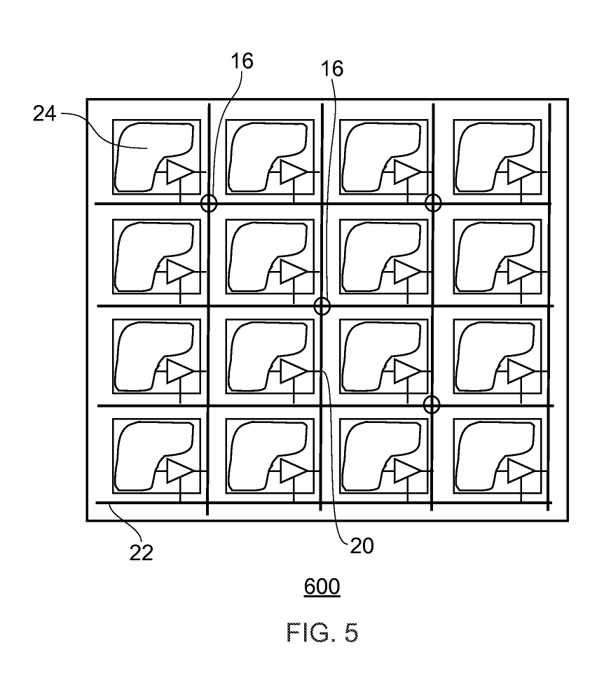

FIGS. 4a and 4b illustrate further example embodiments of the invention. FIG. 4a illustrates the plan view of the substrate 4 and FIG. 4b illustrates the cross-section of the substrate 4. A dielectric layer 10 can be formed on the surface of a semiconductor substrate 4. An opening formed can be formed in the dielectric material 10 and/or the surface of the semiconductor substrate 4. A stopper 16 can be formed at either end of an electrically conductive track 18 comprising a metal such as copper, aluminium or gold formed on the surface of the semiconductor substrate and/or the surface of a dielectric material. The stopper 16 can have a width which is greater than the width of the metal track 18 and can be anchored in the semiconductor die or wafer 4 and/or the dielectric material. Hence the stopper 16 can restrict the differential thermal expansion lengthways of metal track 18, and so reduce failures due to open circuits caused by the differential thermal expansion of the metal track 18 with respect to the semiconductor substrate 4. Although only one metal layer is shown in the FIGS. 4a and 4b it should be appreciated that integrated circuits comprise multiple layers of metal and as a consequence further embodiments may be derived comprising a plurality of stoppers applied to any metal layer within an integrated circuit and/or semiconductor device.

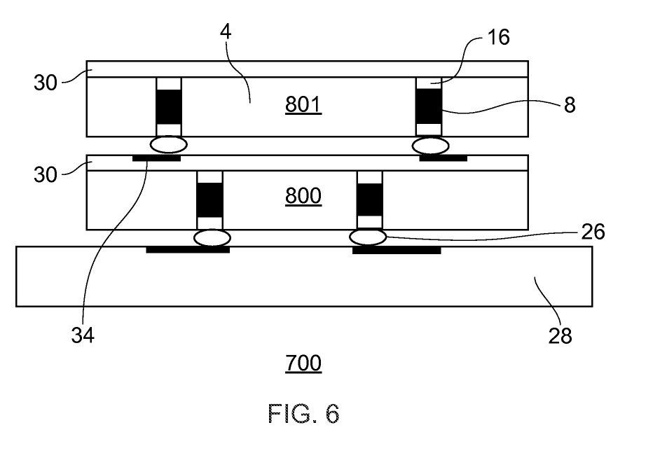

A further example embodiment of the invention is shown in FIG. 6. An integrated circuit 600 comprises an array of a plurality of CMOS image sensors 24 and a plurality of long metal tracks running in either a substantially vertical 20 or substantially horizontal direction 22. At least one stopper 16 can be positioned at the intersection of the long metal tracks 20 and 22. Advantageously, the differential thermal expansion of the substantially vertical long metal tracks 20 with respect to the semiconductor substrate 4 used to form the integrated circuit 600 can be restricted. As a further advantage the differential thermal expansion of the substantially horizontal long metal tracks 22 with respect to the semiconductor substrate 4 used to form the integrated circuit 600 can be restricted. This improves the yield and reliability of the integrated circuit 600, since failures due to open circuits on the long metal tracks 20 and 22 caused by the differential thermal expansion with respect to the semiconductor substrate 4 are reduced. Furthermore longer metal tracks can be formed on integrated circuits 600 than would otherwise be possible without the use of at least one stopper 16. Since longer metal tracks are possible, the example embodiment of the invention allows the fabrication of larger CMOS sensor arrays to be produced than would otherwise be possible without the use of at least one stopper 16.

A further example embodiment of the invention is shown in FIG. 7, wherein a first integrated circuit 800 is stacked on top of a substrate 28 and one or more further integrated circuits 801 are stacked on top of the first integrated circuit 800. The apparatus shown in FIG. 7 is typically known as a stacked die arrangement and can be used to form a System in Package or SiP 700. A substrate material 28 can have a bond pad 32 comprising a metal such as copper, aluminium or gold formed on the surface of the substrate material 28. An integrated circuit 800, having circuitry formed in a plurality of layers 30 can have at least one via 2 formed as a TSV through a semiconductor substrate 4.

The TSV can be partially filled with a metal such as copper forming an electrically conductive track 8, and can have a stopper 16 at each end of the via comprising an electrically conductive material such as tungsten having a lower coefficient of thermal expansion and a higher value of Young's modulus than the electrically conductive track 8. A solder bump 26 can be formed adjacent to the TSV at the opposite side of the semiconductor substrate 4 to the layers forming the circuitry 30. The integrated circuit 800 can be placed on top of the substrate 28 so that the solder bump on the underside of the wafer 26 is adjacent to the bond-pad 34 formed on a surface of the substrate. This forms an electrical connection between the substrate 28 and the circuitry 26 formed on the integrated circuit 800. At least one further integrated circuit 801 can be located on top of the first integrated circuit 800.

The further integrated circuit 801 has circuitry formed in a plurality of layers 30 and can have at least one via 2 formed as a TSV through the semiconductor substrate 4. The TSV can be partially filled with a metal such as copper forming an electrically conductive track 8, and can have a stopper 16 at each end of the via comprising an electrically conductive material such as tungsten, having a lower coefficient of thermal expansion and/or a higher value of Young's modulus than the electrically conductive track 8. A solder bump 26 can be formed adjacent to the TSV at the opposite side of the substrate 4 to the layers forming the circuitry 30. The further integrated circuit 800 can be placed on top of the first integrated circuit 801 so that the solder bump on the underside of the wafer 26 is adjacent to the bond-pad 34 formed on a surface of the first integrated circuit. This can form an electrical connection between the substrate 28 and the circuitry 26 formed on the integrated circuit 800. At least one further integrated circuit 801 can be located on top of the first integrated circuit 800. The solder bumps 26 of a further integrated circuit 801 can be adjacent to bond pads comprising a metal such as copper formed on the first integrated circuit 800. This can form an electrical connection between circuitry 30 on the first integrated circuit and the circuitry 30 on the further integrated circuit 801.

Advantageously the example embodiment of the invention in FIG. 7 can improve the reliability of a stacked die assembly since the differential thermal expansion of the metal substantially filling the TSV 8 compared to the semiconductor substrate 4 can be restricted. This may prevent failures such as the dies separating from each other due to the expansion of the material in the TSVs. As a further advantage, the use of stoppers in TSVs as shown in the example embodiment of the invention can prevent sheer stresses in the semiconductor substrate which may cause the substrate to crack. A further advantage is that using a material 8 such as copper to substantially fill the via 2 together with a stopper 16 comprising a material such as tungsten has a lower resistance than filling the via solely with a material such as tungsten.

Accordingly, there has been described an apparatus for restricting the thermo-mechanical stress in semiconductor wafers both during manufacture, and during the operating lifetime of the semiconductor devices and systems formed on the wafer. An electrically conductive track 8 can be formed with a stopper 16 which can be positioned at least at one end of the electrically conductive track 8. The differential expansion during heating of electrically conductive tracks 8 with respect to a semiconductor wafer 4 can be restricted by the stopper 16.

Although particular embodiments of the invention have been described, it will be appreciated that many modifications/additions and/or substitutions may be made within the scope of the claimed invention.

1. An apparatus comprising:
a first semiconductor substrate comprising a first material;
at least one electrically conductive track located in the semiconductor substrate, wherein the electrically conductive track comprises a second material having a thermal expansion coefficient that is different to a thermal expansion coefficient of the first material; and
at least one stopper positioned to at least partially restrict thermal expansion of the electrically conductive track relative to the semiconductor substrate.

2. An apparatus according to claim 1, wherein the stopper is made from a third material that has a lower coefficient of thermal expansion than the second material forming the electrically conductive track.

3. An apparatus according to claim 2, wherein the stopper is made from a third material that has a higher value of Young's modulus than the second material forming the electrically conductive track.

4. An apparatus according to claim 2, wherein the value of the thermal coefficient of expansion of the third material forming the stopper is not greater than twice the value of the thermal coefficient of expansion of the first material forming the semiconductor substrate.

5. An apparatus according to claim 3, wherein the value of Young's modulus of the third material forming the stopper is at least twice the value of Young's modulus of the second material forming the electrically conductive track.

6. An apparatus according to claim 5, wherein the value of Young's modulus of the third material forming the stopper is between 10 percent and 1000 percent of the value of Young's modulus of the first material forming the semiconductor substrate.

7. An apparatus according to claim 1, wherein at least a portion of the electrically conductive track is located substantially within an opening formed in the surface of the semiconductor substrate, and wherein a stopper is at least partially received within the opening.

8. An apparatus according to claim 7, wherein the opening comprises a via through the semiconductor substrate and wherein a stopper is positioned at least at one end of the via.

9. An apparatus according to claim 1, wherein the electrically conductive track is located on the surface of the semiconductor substrate and wherein at least one stopper is positioned along the electrically conductive track on the surface of the semiconductor substrate.

10. An apparatus according to claim 9, wherein the stopper is anchored to the surface of the semiconductor substrate.

11. An apparatus according to claim 10, wherein at least a portion of the stopper is received in a hole formed in the surface of the semiconductor substrate.

12. An apparatus according to claim 1, wherein the electrically conductive track comprises at least one of copper, aluminium and gold and wherein the stopper comprises at least one of tungsten and molybdenum.

13. An apparatus according to claim 12, wherein the electrically conductive track comprises copper and wherein the stopper comprises tungsten.

14. An apparatus according to claim 1, comprising a grid having at least one electrically conductive track and at least one further electrically conductive track; wherein at least one stopper is located at a point of intersection of the electrically conductive track and the further electrically conductive track.

15. An apparatus according to claim 1 and comprising a further semiconductor substrate, wherein the further semiconductor substrate is located on top of the first semiconductor substrate, adjacent the electrically conducting track.

16. An apparatus according to claim 15, wherein the further semiconductor substrate comprises the first material and further comprises;
at least one electrically conductive track located on or in the further semiconductor substrate, wherein the further electrically conductive track comprises the second material; and
at least one stopper positioned to at least partially restrict thermal expansion of the electrically conductive track during heating of the further semiconductor substrate.

17. An integrated circuit chip comprising the apparatus according to claim 1.
